(19) United States
(12) Patent Application Publication
(10) Pub. No.: US 2026/0032826 A1
(43) Pub. Date: Jan. 29, 2026

(54) SHEARING DEVICE AND METHOD FOR REMOVING SAPPHIRE SUBSTRATE

(71) Applicant: Lumileds LLC, San Jose, CA (US)

(72) Inventors: Joyce Chan Li Kin, Singapore (SG); Chee Chung James Wong, Singapore (SG); Yeow Meng Teo, Singapore (SG)

(73) Assignee: Lumileds LLC, San Jose, CA (US)

(21) Appl. No.: 18/994,779

(22) PCT Filed: Aug. 18, 2023
(86) PCT No.: PCT/US2023/030614

§ 371 Date: Jan. 15, 2025

Related U.S. Application Data
(60) Provisional application No. 63/371,998, filed on Aug. 19, 2022.

(51) Int. Cl. H05K 3/22

(52) U.S. Cl. CPC H05K 3/22; H05K 2203/176

(57) ABSTRACT

A light emitting diode (LED) device sapphire substrate removal apparatus and method are disclosed. The apparatus and method includes placing the LED device comprising a sapphire substrate and a carrier onto stage sized and shaped to hold the carrier of the LED device and applying a force with a shearing blade to the sapphire substrate to separate the sapphire substrate from the carrier. The apparatus include the stage and a sapphire substrate shearing device.

### TECHNICAL FIELD

Embodiments of the disclosure generally relate to light emitting devices, and in particular, post laser lift-off of materials and structures for removing layers, such as sapphire substrates, from light emitting diode (LED) devices during the manufacture of LEDs.

### BACKGROUND

Layers are commonly grown on a carrier or a substrate, such as a sapphire substrate, to form LEDs. A few examples of epitaxial (EPI) layer materials include gallium nitride (GaN), aluminum gallium nitride (AlGaN), aluminum nitride (AlN), indium nitride (InN) and indium gallium nitride (InGaN). In this disclosure, a GaN layer will be used as a non-limiting example for an exemplary description of a laser lift-off (LLO) process.

As shown in FIG. 1, a prior art laser lift-off process 100 is used to separate a substrate, such as a sapphire substrate 104, from a GaN interface 106 of an LED device 101 using a laser source 102. The sapphire substrate 104 is on the GaN interface 106, which is on an interconnect 108, which is mounted on a carrier 110 (which can also be referred to as a sub-mount or sub-mount tile), such that the interconnect 108 is disposed between the GaN interface 106 and the carrier 110. This technique has been used to increase the luminous efficiency of GaN-based LEDs. The sapphire substrate 104, the GaN interface 106, and the interconnect 108 are bonded onto the carrier 110 by an underfill adhesive disposed between the interconnect 108 and the carrier 110. Conventional laser lift-off methods used in LED manufacturing processes use a single shot laser beam. The laser source 102 generates a laser beam that is directed towards and passes through the sapphire substrate 104 and is absorbed by the GaN interface 106 at high temperatures. Thermal decomposition of the GaN interface 106 occurs when high energy from the laser source 102 induces local heating on the GaN interface 106 above the critical sublimation temperature of gallium (Ga), forming metallic Ga and gaseous nitrogen (N₂) as shown in the equation: 2GaN(s)→2Ga(l)+N₂(g). Removal of the sapphire substrate 104 occurs via the instantaneous N₂ vaporization pressure generated, which lifts the sapphire substrate 104 from the GaN interface 106.

A challenge in sapphire substrate removal is that sapphire can be melted onto the GaN interface layer during the laser lift-off process. In some instances, the sapphire substrate 104 melts and forms one or more forms of alumina (aluminum oxide), for example, crystalline alumina such as alpha alumina or polycrystalline alumina or amorphous alumina. These different forms of alumina form at high temperature due to partial transmission and reflection amplitudes when the laser moves from a low (sapphire) to high (GaN) refractive index medium, causing rapid cooling. When rapid cooling occurs, the alumina will stick to the GaN and sapphire surfaces. This may cause the sapphire substrate to remain intact and prevent the laser lift-off from removing the sapphire substrate from the GaN interface.

There is a need to address the challenges of sapphire substrate removal after a laser lift-off process in which the sapphire substrate remains adhered to the GaN interface.

### SUMMARY

An aspect of the disclosure pertains to a light emitting diode (LED) device sapphire substrate removal apparatus comprising a stage including at least a first carrier holder sized and shaped to hold a carrier of an LED device including a sapphire substrate, the carrier holder comprising a recessed region defining an area configured to receive the carrier and a raised edge configured to hold the carrier when removing the sapphire substrate from the LED device; and a shearing device comprising a shearing blade positioned to apply a force to the sapphire substrate to remove the sapphire substrate from the LED device.

Embodiments according to this aspect can include one or more of the following features. The shearing blade is movably disposed in a vertical direction with respect to the first carrier holder. The shearing blade is movably disposed in a horizontal direction with respect to the first carrier holder. The shearing device comprises a motor and a shaft in connection with the shearing device, wherein the motor and shaft are configured to move the shearing blade horizontally and/or vertically with respect to the first carrier holder. The stage is enclosed by one or more walls. The stage further comprises a trough disposed along a side of the stage for receiving the sapphire substrate after removal from the LED device. A vacuum suction device is provided in fluid communication with the stage. The shearing blade comprises a metal having a hardness greater than or equal to the hardness of sapphire. The stage is mounted to a pedestal configured to move the stage in a vertical direction. The light emitting diode (LED) device sapphire substrate removal apparatus further comprises a controller configured to control movement of the shearing blade.

Another aspect of the disclosure pertains to a method of removing a sapphire substrate from an LED device, the method comprising placing the LED device comprising the sapphire substrate and a carrier onto a stage; and using a shearing device to apply a force to the sapphire substrate to remove the sapphire substrate from the LED device.

Embodiments according to this aspect can include one or more of the following features. The stage includes at least a first carrier holder sized and shaped to hold the carrier of the LED device, wherein the carrier holder comprises a recessed region defining an area configured to receive the carrier and a raised edge configured to hold the carrier, and placing the LED device onto the stage comprises placing the carrier into the recessed region such that the raised edge holds the carrier with the sapphire substrate positioned above the raised edge. The shearing device comprises a shearing blade, and applying the force to the sapphire substrate comprises moving the shearing blade relative to the first carrier holder to apply the force to the sapphire substrate. The shearing blade is movable relative to the first carrier holder in at least one of a vertical direction and a horizontal direction, and applying the force to the sapphire substrate comprises moving the shearing blade in at least one of a vertical direction and a horizontal direction. The method further comprises, prior to applying the force to the sapphire substrate to remove the sapphire substrate from the LED device, moving the shearing blade in at least one of a vertical direction and a horizontal direction to position the shearing blade adjacent the sapphire substrate. Applying the force to the sapphire substrate to remove the sapphire substrate from the LED device comprises moving the shearing blade horizontally to engage and separate the sapphire substrate from the LED device. The method further comprises discarding the sapphire substrate removed from the LED device in a trough disposed in the stage. The method further comprises removing the sapphire substrate from the trough using a vacuum suction device in fluid communication with the stage. The shearing device comprises a motor and a shaft configured to move the shearing blade horizontally and vertically relative to the first carrier holder. The stage is mounted to a pedestal configured to move the stage in a vertical direction.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements. The figures herein are not to scale.

FIG. 1 is a schematic view illustrating a prior art laser lift-off process to remove a sapphire substrate from a light emitting diode die;

FIG. 2A is a perspective view of a shearing device for removing a sapphire substrate from a light emitting diode (LED) device according to one or more embodiments;

FIG. 2B is a top perspective view of a shearing apparatus for removing a sapphire substrate from a light emitting diode (LED) according to one or more embodiments, the shearing apparatus including the shearing device shown in FIG. 2A;

FIG. 2C is a cross-sectional side view of the shearing apparatus for removing a sapphire substrate from a light emitting diode (LED) shown in FIG. 2B;

FIG. 2D is a bottom view of the shearing apparatus for removing a sapphire substrate from a light emitting diode (LED) shown in FIG. 2B;

FIG. 3A is a top perspective view of the shearing apparatus for removing a sapphire substrate from a light emitting diode (LED) shown in FIG. 2B in use, with a tip of the shearing device positioned above the LED;

FIG. 3B is an enlarged cross-sectional side view of the shearing apparatus for removing a sapphire substrate from a light emitting diode (LED) shown in FIG. 3A;

FIG. 4A is a top perspective view of the shearing apparatus for removing a sapphire substrate from a light emitting diode (LED) shown in FIG. 2B in use, with a tip of the shearing device positioned adjacent to and engaging the LED;

FIG. 4B is an enlarged cross-sectional side view of the shearing apparatus for removing a sapphire substrate from a light emitting diode (LED) shown in FIG. 4A;

FIG. 5A is a top perspective view of the shearing apparatus for removing a sapphire substrate from a light emitting diode (LED) shown in FIG. 2B in use, with a tip of the shearing device pushing the sapphire substrate partially off the LED;

FIG. 5B is an enlarged cross-sectional side view of the shearing apparatus for removing a sapphire substrate from a light emitting diode (LED) shown in FIG. 5A;

FIG. 6A is a schematic showing the shear force applied to the sapphire substrate during a sapphire substrate removal operation;

FIG. 6B is a graph illustrating the effect of applied forces by the apparatus and method according to one or more embodiments;

FIG. 7 is a flow chart illustrating a method according to one or more embodiments; and

FIG. 8 is a perspective view illustrating removal of a sapphire substrate from an LED die including a trenched metal grid.

### DETAILED DESCRIPTION

Before describing several exemplary embodiments of the disclosure, it is to be understood that the disclosure is not limited to the details of construction or process steps set forth in the following description. The descriptions in the disclosure are capable of other embodiments and of being practiced or being carried out in various ways.

Reference to an LED (or the plural, LEDs) refers to a light emitting diode device at the wafer or the die level that emits light when current flows through the LED. In one or more embodiments, the LEDs herein have one or more characteristic dimensions (e.g., height, width, depth, thickness, etc. dimensions). In one or more embodiments, the length and the width are in a range from about 1 mm to about 350 mm. In one or more embodiments, one or more dimensions of height, width, depth, and thickness have values in a range of from about 1 mm to about 300 mm, from about 1 mm to about 150 mm, or from about 1 mm to about 100 mm. LED devices according to some embodiments include micro-LEDs (uLEDs or μLEDs), referring to a light emitting diode having one or more characteristic dimensions (e.g., height, width, depth, thickness, etc. dimensions) of less than 100 micrometers. In one or more embodiments, one or more dimensions of height, width, depth, and thickness of an LED die have values in a range of from about 1 mm to about 300 mm, for example, from about 1 mm to about 75 mm, for example from about 1 mm to about 50 mm, from about 1 mm to about 25 mm, from about 2 mm to about 25 mm, or from about 3 mm to about 15 mm. Overall, in one or more embodiments, the LEDs herein may have a characteristic length and width dimension ranging from about 1 mm to about 350 mm, and all values and sub-ranges therebetween. The thickness dimension of various semiconductor layers and the sapphire substrate may be expressed in micrometers. For example, in some embodiments, the semiconductor layers (such as the GaN interface 106) discussed herein have a thickness in a range of from about 2 μm to about 50 μm, for example from about 2 μm to about 30 μm, or about 2 μm to about 20 μm. In some embodiments, the thickness of the sapphire substrate 104 is in a range of from about 100 μm to about 800μ m.

LEDs capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a growth substrate such as a sapphire, silicon carbide, Ill-nitride, or other suitable substrate by metal-organic chemical vapor deposition (MOCVD), molecular beam epitaxy (MBE), or other epitaxial techniques. Sapphire is often used as the growth substrate due to its wide commercial availability and relative ease of use. The stack grown on the growth substrate typically includes one or more n-type layers doped with, for example, Si, formed over the substrate, a light emitting or active region formed over the n-type layer or layers, and one or more p-type layers doped with, for example, Mg, formed over the active region. An LED die is a structure including a substrate and the stack of semiconductor layers.

Methods of depositing materials, layers, and thin films to form LEDs include but are not limited to: sputter deposition, atomic layer deposition (ALD), chemical vapor deposition (CVD), physical vapor deposition (PVD), plasma enhanced atomic layer deposition (PEALD), plasma enhanced chemical vapor deposition (PECVD), and combinations thereof.

Methods of forming or growing semiconductor layers including n-type layers, active regions, and p-type layers can be in accordance with methods known in the art. In one or more embodiments, the semiconductor layers are formed by epitaxial (EPI) growth. The semiconductor layers according to one or more embodiments comprise epitaxial layers, Ill-nitride layers, or epitaxial Ill-nitride layers. In one or more embodiments, the semiconductor layers comprise a III-nitride material, and in specific embodiments, an epitaxial III-nitride material. In some embodiments, the III-nitride material comprises one or more of gallium (Ga), aluminum (Al), and indium (In). Thus, in some embodiments, the semiconductor layers comprise one or more of gallium nitride (GaN), aluminum nitride (AlN), indium nitride (InN), aluminum gallium nitride (AlGaN), indium gallium nitride (InGaN), indium aluminum nitride (InAlN), aluminum indium gallium nitride (AlInGaN), and the like. The III-nitride materials may be doped with one or more of silicon (Si), oxygen (O), boron (B), phosphorus (P), germanium (Ge), manganese (Mn), or magnesium (Mg) depending upon whether p-type or n-type III-nitride material is needed. In one or more embodiments, the semiconductor layers have a combined thickness in a range of from about 2 μm to about 10 μm, and all values and subranges therebetween.

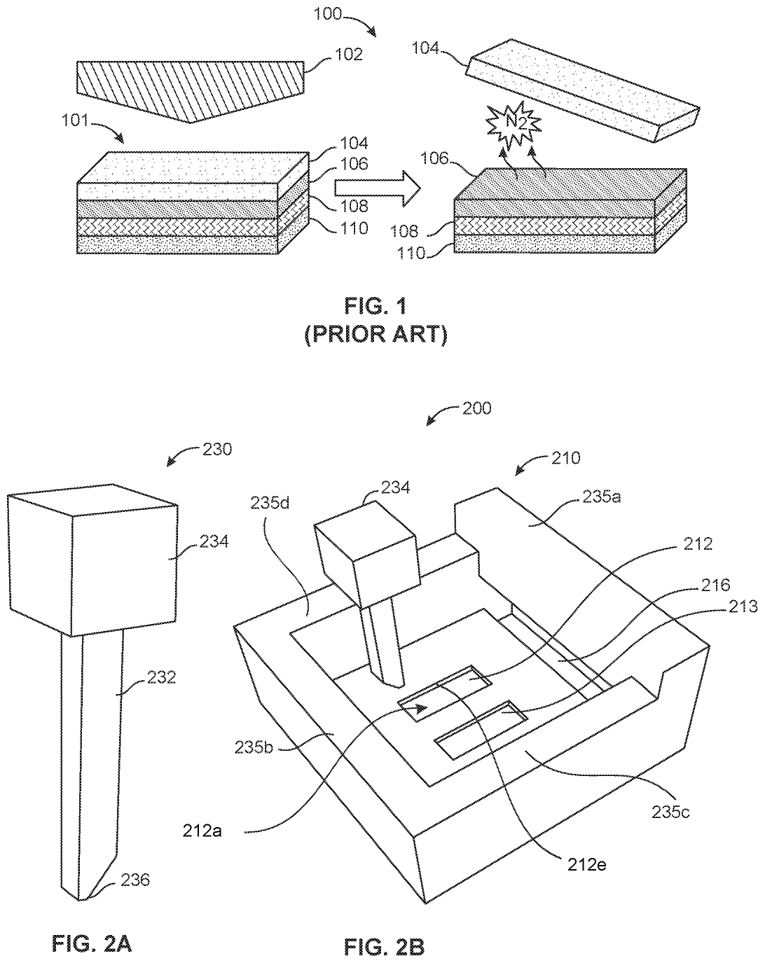

Thus, according to one or more embodiments, in the manufacture of an LED, a GaN interface 106 is formed on a sapphire substrate 104, followed by one or more n-type layers, one or more active layers, and one or more p-type layers that form the interconnect 108 (e.g., as shown in FIG. 1). Metallic conductors may be formed through and upon one or more of the layers to provide coupling of the n-type and p-type layers to an external source of power to activate the active layer(s) of the light emitting element, via contact pads above the uppermost (p-type) layer.

As discussed above, laser lift-off is a process that is commonly used to remove the sapphire substrate from an LED device. A laser pulse is projected toward and through the sapphire substrate and is absorbed by the semiconductor layer at the sapphire-semiconductor interface, causing thermal decomposition of the semiconductor layer at the interface. The laser pulse in some embodiments comprises multiple pulsed laser shots that are stitched together (e.g., by raster scanning multiple smaller laser beams) to cover an entire area of a sapphire substrate that is removed at the wafer level or from a die comprising multiple LEDs. In other embodiments, the laser pulse is a single shot laser that covers the entire area of a sapphire substrate that is removed at the wafer level or from a die comprising multiple LEDs. In a specific embodiment, a single shot laser is used, comprising an ArF excimer laser with a flat top beam having a beam size in a range from 1 mm×1 mm to 2.2 mm×2.7 mm, which is useful for dies up to 2.2 mm×2.7 mm (width×length). In another specific embodiment, a KrF excimer laser is used for laser lift-off of a micro-LED, using a flat top laser beam having a beam size in a range from 200 micrometers×200 micrometers to 500 micrometers×500 micrometers. By using beam stitching, laser lift-off can be performed on micro-LED die sizes greater than 2.2 mm×2.7 mm (width×length) and as defined herein for micro-LEDs. In another specific embodiment, wafer level laser lift-off is performed using a KrF excimer laser having a flat top beam having a beam size in a range from 200 micrometers×200 micrometers to 500 micrometers×500 micrometers. By using beam stitching, laser lift-off can be performed at the wafer level.

As discussed above, when the laser lift-off process does not succeed in removing the sapphire substrate from the GaN interface, the sapphire substrate is adhered to the GaN interface and, unless it is removed, the wafer or die will have to be discarded, resulting in a loss of process yields, valuable material, and manufacturing time. Thus, one or more embodiments described herein solves an important problem by providing apparatus and methods to complete lift-off or removal of the sapphire substrate when the laser lift-off process has not resulted in removal of the sapphire substrate from the GaN interface, solving an expensive and difficult problem.

In one or more embodiments in which the laser lift-off and the subsequent sapphire removal described by the method and apparatus described in this disclosure are performed at the wafer level, the wafer-size sapphire substrate is removed after the whole wafer has been processed. In other embodiments, in which the laser lift-off and the subsequent sapphire substrate removal described by the method and apparatus described in this disclosure are performed for each individual die, the dies are flip-chip mounted on the carrier 110 (or sub-mount) (e.g., as shown in FIG. 1), with the sapphire substrate 104 facing upward. The laser is applied to each die, and the die-size sapphire chips are removed after the laser is incident on each die, leaving the semiconductor structure on the carrier 110.

Accordingly, the methods and apparatus described herein can be implemented at the die level (e.g. as shown in FIG. 1) or at the wafer level. According to one or more embodiments, after a laser lift-off process in which thermal decomposition aids in the separation of a sapphire substrate from a LED device, but the sapphire substrate has not been fully removed, a shearing method and/or shearing device and apparatus can be used to complete removal of the sapphire substrate from the LED device. In one or more embodiments, a shearing method utilizes a customized tool described herein.

In one or more embodiments, after a laser lift-off process, a tape frame populated with LED devices undergoes ultraviolet cure, and then a pick and place (PnP) step is utilized to further process the LED devices to remove the sapphire substrate. Using a single LED device as an example, the LED device is picked from the ultraviolet cured tape frame and placed onto a carrier so that the sapphire substrate can be removed according to the apparatus and methods described herein.

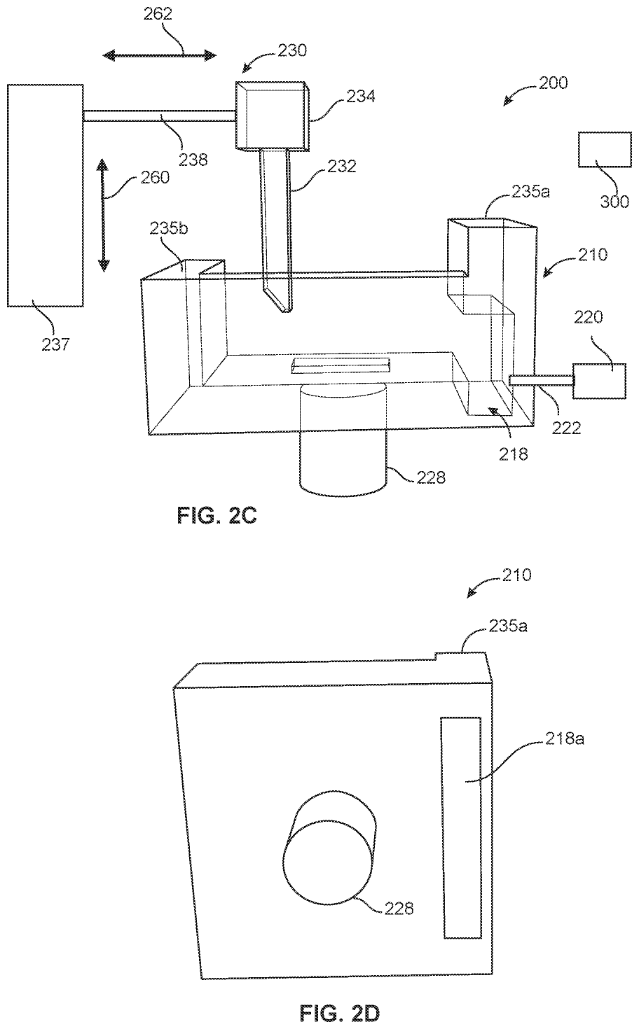

Referring now to FIGS. 2A-D, a first aspect of the disclosure pertains to light emitting diode (LED) device sapphire substrate removal apparatus 200 comprising a stage 210 including at least a first carrier holder 212 sized and shaped to receive and hold a carrier 110 of an LED device 101 including a sapphire substrate 104. The first carrier holder 212 comprises a recessed region defining an area 212a configured to receive the carrier 110, and a raised edge 212e configured to hold the carrier 110 during a sapphire substrate 104 removal operation. According to one or more embodiments, the stage 210 includes at least a second carrier holder 213 having the same general features and configuration as the first carrier holder 212. As shown in FIG. 2B, the second carrier holder 213 (and any additional carrier holders) can be disposed in the stage generally in line with and parallel to the first carrier holder 212. The sapphire substrate removal apparatus 200 further comprises a shearing device 230 comprising a shearing blade 232 movably positioned with respect to the stage 210 to apply a force to the sapphire substrate 104 to remove the sapphire substrate 104 from the LED device 101. In some embodiments, the shearing device 230 is movably positioned to apply a lateral force that shears the sapphire substrate 104 from the LED device, and the force is referred to as a shearing force. As best shown in FIG. 2A, the shearing device 230 comprises the shearing blade 232 extending from a shearing blade holder 234. The shearing blade 232 includes an angled tip 236 at a distal end, which is the portion of the shearing blade 232 that contacts the sapphire substrate 104 during the removal operation. In one or more embodiments, the shearing device 230 and the shearing blade 232 are movable with respect to the first carrier holder 212 (and any additional carrier holders) in a vertical direction as indicated by arrow 260 in FIG. 2C. In one or more embodiments, the shearing device 230 and the shearing blade 232 are movable in a horizontal direction with respect to the first carrier holder 212 (and any additional carrier holders) as indicated by the arrow 262 in FIG. 2C.

In the embodiments shown, and as best shown in FIG. 2C, the shearing device 230 further comprises a motor 237 and a shaft 238 configured to move the shearing blade 232 horizontally with respect to the first carrier holder 212 (and any additional carrier holders). In one or more embodiments, the motor 237 is mounted to a fixture (not shown) adjacent to the sapphire substrate removal apparatus 200, or in other embodiments the motor is mounted to the stage 210 (not shown). In some embodiments the motor 237 (or a separate motor, not shown) is configured to move the shearing blade 232 vertically with respect to the first carrier holder 212 (and any additional carrier holders).

In the embodiment shown, the stage 210 is enclosed by walls, including a first wall 235a, a second wall 235b opposite the first wall 235a, a third wall 235c between the first wall 235a and the second wall 235b, and a fourth wall 235d opposite the third wall 235c. In one or more embodiments, as best seen in FIG. 2B, the first wall 225a has a height greater than the second wall 235b, the third wall 235c and the fourth wall 235d. In the embodiment shown, the stage 210 comprises a trough 218 extending between the third wall 235c and the fourth wall 235d. In some embodiments, the trough 218 extends along and generally parallel to the first wall 235a The trough 218 comprises a recessed region in the stage 210 at least equal to, and preferably greater in depth than, a depth of the first carrier holder 212 recessed region. The trough 218 is configured to collect a sapphire substrate 104 that has been removed from an LED device 101. In some embodiments, as shown in FIG. 2D, the trough may include a door 218a to facilitate removal of discarded sapphire substrates 104.

In some embodiments, as shown for example in FIG. 2C, the sapphire substrate removal apparatus 200 comprises a vacuum suction device 220 in fluid communication with the stage 210 to remove discarded sapphire substrates. In some embodiments, there is a suction line 222 connecting the stage 210 and the vacuum suction device 220. In one or more embodiments, the suction line 222 is in the form of a hose or metal conduit. In some embodiments, the suction line 222 and the suction device 220 are in fluid communication with the trough 218, and the suction line 222 connects the trough 218 and the vacuum suction device 220. The vacuum suction device 220 can comprise any suitable vacuum suction device used in an industrial setting to remove particles or waste.

In one or more embodiments, the first carrier holder 212 is sized and shaped to receive and hold a carrier 110 having a dimension in a range from about 1 millimeter to about 350 millimeters, for example about 75 millimeters to about 350 millimeters or about 75 millimeters to about 300 millimeters. In other embodiments, the first carrier holder 212 is sized to hold a carrier having a dimension in a range of about 1 millimeter to about 75 millimeters, for example about 1 millimeter to about 50 millimeters, about 1 millimeter to about 25 millimeters, about 2 millimeters to about 25 millimeters or about 3 millimeters to about 15 millimeters.

Since sapphire is a hard material (hardness of 9 on the Mohs scale), the shearing blade 232 is generally fabricated of a hard material. For example, in some embodiments the shearing blade 232 may comprise a metal, particularly a hard metal. According to some embodiments, the shearing blade 232 is fabricated of a material at least as hard as sapphire (i.e., a hardness of at least about 9 on the Mohs scale), such as tungsten carbide. The shearing blade 232 may also or may alternatively be coated with a suitable hard material having a hardness equal to or greater than sapphire, such as a diamond coating (hardness of 10 on the Mohs scale). In some embodiments, the stage 210 is mounted to a pedestal 228 (e.g., as shown in FIGS. 2C-2D). In one or more embodiments, the pedestal 228 is configured to move the stage 210 in a vertical direction. In one or more embodiments, the sapphire substrate removal apparatus 200 comprises a metal, such as stainless steel, and the stage 210 comprises a metal, such as stainless steel.

In some embodiments, the sapphire substrate removal apparatus 200 comprises a controller 300 configured to control movement of the shearing device 230 and shearing blade 232. The controller 300 generally includes a central processing unit (CPU), memory, and support circuits. The CPU may be one of any form of a general-purpose processor that can be used in an industrial setting. The memory, or non-transitory computer-readable medium, is accessible by the CPU and may be one or more of memory such as random-access memory (RAM), read only memory (ROM), floppy disk, hard disk, or any other form of digital storage, local or remote. The support circuits are coupled to the CPU and may comprise cache, clock circuits, input/output subsystems, power supplies, and the like. The various methods disclosed herein may generally be implemented under the control of the controller 300 by the CPU executing computer instruction code stored in the memory as, for example, a software routine. When the computer instruction code is executed by the CPU, the CPU controls the components of the sapphire substrate removal apparatus 200 to perform processes in accordance with the various methods. In one or more embodiments, some or all of the methods of the present disclosure are controlled hardware. As such, in some embodiments, the processes are implemented by software and executed using a computer system, in hardware as, e.g., an application specific integrated circuit or other type of hardware implementation, or as a combination of software and hardware.

In some embodiments, the vacuum suction device 220 is in communication with the controller 300. The controller 300 can coordinate movement of the shearing blade 232 to remove sapphire substrates 104 and a cleaning operation to clean discarded sapphire substrates 104 from the stage 210 and the trough 218.

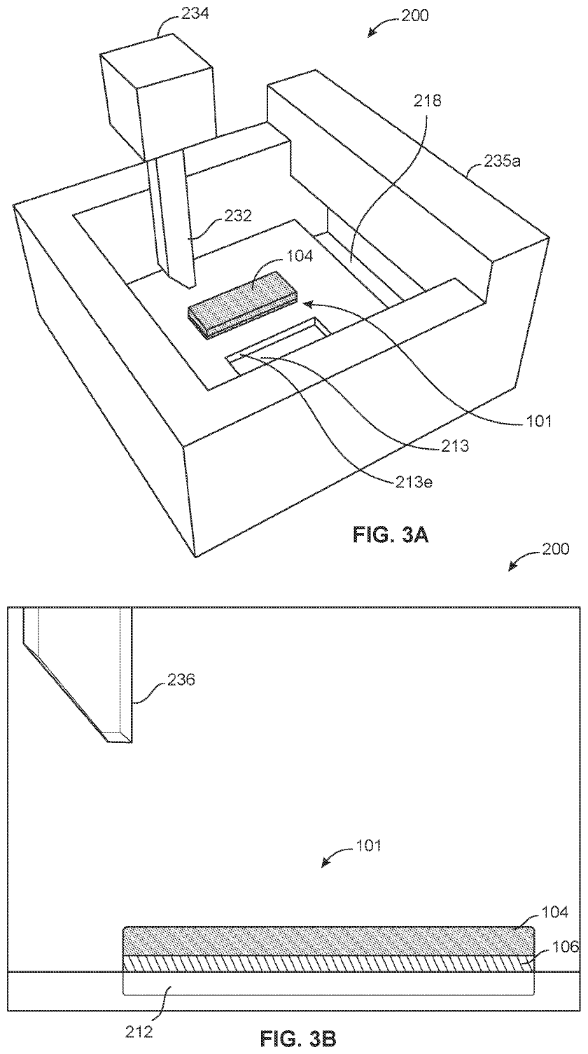

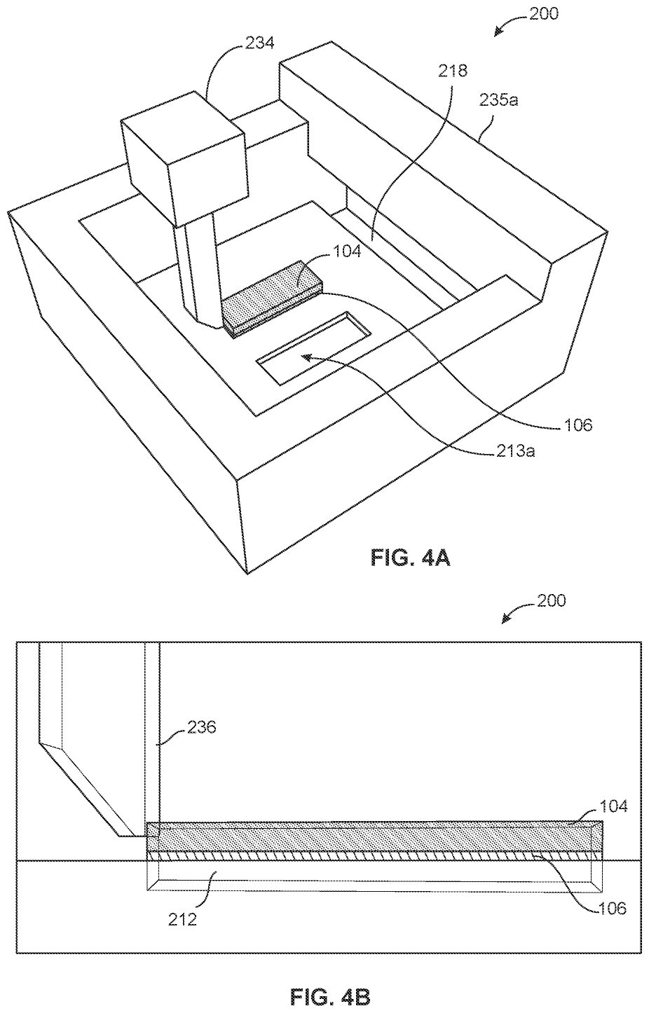

FIGS. 3A-B show the sapphire substrate removal apparatus 200 in use at a first stage of a sapphire substrate removal operation in which the tip 236 of the shearing blade 232 is positioned above the LED device 101 which is disposed in the first carrier holder 212. An empty second carrier holder 213 comprising a recessed region defining an area 213a (see FIG. 4A) configured to receive a carrier and a raised edge 213e configured to hold a carrier is depicted disposed in the stage 210 next to the first carrier holder 212.

FIGS. 4A-B show the sapphire substrate removal apparatus 200 in use at a second stage of a sapphire substrate removal operation in which the tip 236 of the shearing blade 232 positioned adjacent the LED device 101 placed in the first carrier holder 212. In particular, the tip 236 of the shearing blade 232 is adjacent to the sapphire substrate 104. The controller 300 has executed instructions to lower the shearing blade 232 to the proper height and the shearing blade 232 has been moved horizontally to engage the sapphire substrate 104 to commence the removal operation.

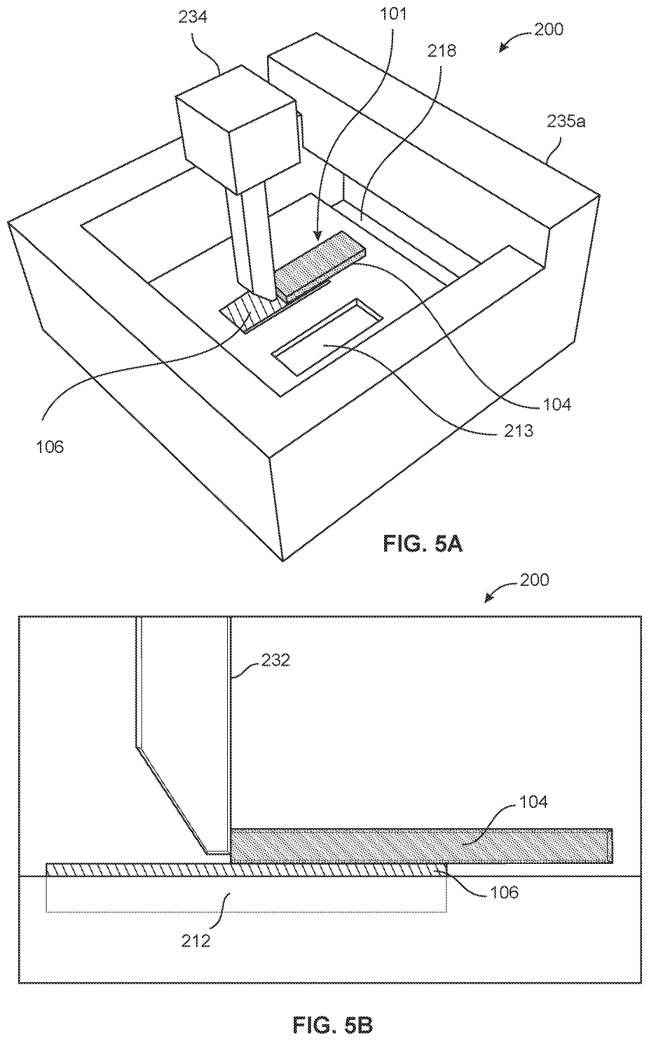

FIGS. 5A and 5B show the sapphire substrate removal apparatus 200 in use at a third stage of a sapphire substrate removal operation in which the tip 236 of the shearing blade 232 is forcing the sapphire substrate off the LED device 101. In particular, the tip 236 of the shearing blade 232 has pushed the sapphire substrate 104 partially off the LED device 101. The controller 300 has executed instructions move the shearing blade 232 using sufficient force to overcome the force holding the sapphire substrate 104 to the LED device 101. The operation continues until the sapphire substrate 104 has been completely removed and the sapphire substrate 104 is collected in the trough 218. The controller 300 executes instructions to activate the vacuum suction device 220 to remove discarded sapphire substrates 104.

Thus, after the sapphire substrate 104 has been detached from GaN interface 106 of the LED device 101, the sapphire substrate 104 is collected by the suction at the end of the enclosed stage 210. The LED device 101 with sapphire substrate 104 removed therefrom can then be removed from the stage 210 using a pick and place (PnP) device, and the LED device 101 is placed onto a new tape frame before proceeding to a next processing step in a manufacturing process.

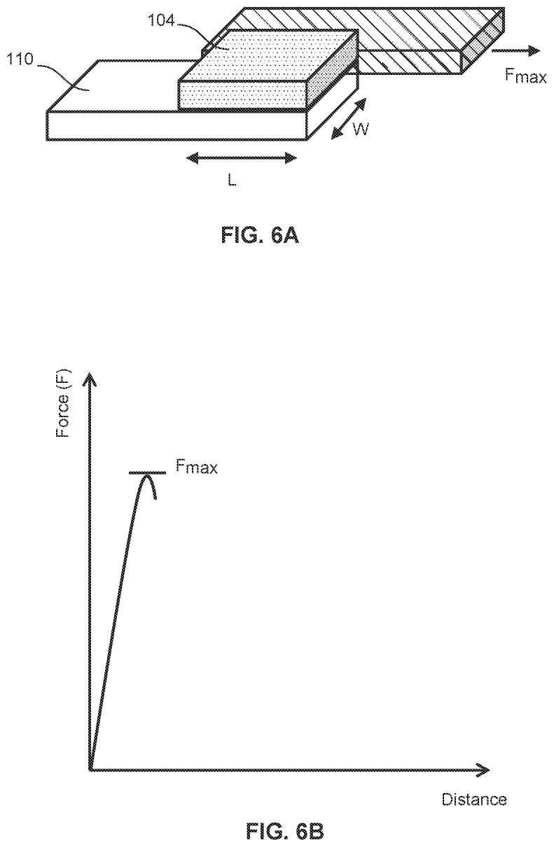

Referring now to FIGS. 6A and 6B, a shear force is an external force acting parallel to a surface area defined by a length L and a width W, pushing the material of the sapphire substrate 104 towards the same direction as the force with the material having resistance against the shear force until it reaches failure. Shear strength can be calculated using Equation 1.

$$τ = \frac{F}{A} \qquad Equation 1$$

In one or more embodiments, the principle of lap shear strength can be explained as a maximum shearing force on the sapphire substrate 104 before the sapphire substrate 104 detaches from the bonding strength between the sapphire substrate 104 and the GaN interface 106 layer with respect to distance. FIG. 6B shows the relationship between force and distance. Therefore, the bonding strength between the sapphire substrate 104 and the GaN interface 106 layer is equal to the lap shear strength at which the sapphire substrate 104 starts to detach from the GaN interface 106. The formula is as shown in Equation 2.

$${τ}_{bond} = \frac{{F}_{m a x}}{A} \qquad Equation 2$$

Where Fmax=increasing force until point of separation, and A=bonding area between the sapphire substrate 104 and GaN interface 106.

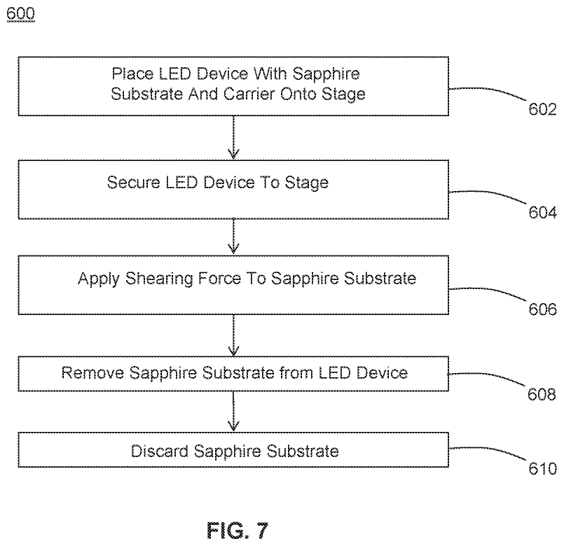

Referring now to FIG. 7, another aspect of the disclosure pertains to a method 600 of removing a sapphire substrate 104 from an LED device 101. In one embodiment, the method 600 comprises placing the LED device 101 comprising a sapphire substrate 104 and a carrier 110 onto a stage 210 (operation 602). The method can further comprise securing the LED device 101 to the stage 210 to prevent the carrier 110 of the LED device 101 from moving during removal of the sapphire substrate 104 (operation 604). A force is then applied to the sapphire substrate 104 (operation 606), the sapphire substrate 104 is removed from the LED device 101 using a force (operation 608), and the sapphire substrate 104 is discarded (operation 610).

In some embodiments, the method further comprises placing the LED device 101 on the stage 210 including a first carrier holder 212 sized and shaped to hold the carrier 110 of an LED device 101. The first carrier holder 212 comprises a recessed region defining an area 212a configured to receive the carrier 210 and a raised edge 212e configured to hold the carrier 210 during a sapphire substrate removal operation.

Applying the force can include using a shearing device 230 comprising a shearing blade 232 positioned to apply the force to the sapphire substrate 104 to separate the sapphire substrate 104 from the LED device 101. In some embodiments, the shearing blade 232 is movable with respect to the first carrier holder 212 in a vertical direction. In some embodiments, the shearing blade 232 is movable in a horizontal direction with respect to the first carrier holder 212.

One or more method embodiments comprise moving the shearing blade 232 in the vertical direction to place the shearing blade 232 adjacent to the sapphire substrate 104 and then moving the shearing blade 232 in the horizontal direction to contact the sapphire substrate 104. In some embodiments, the shearing device 230 used in the method further comprises a motor 237 and a shaft 238 configured to move the shearing blade 232 horizontally and/or vertically with respect to the first carrier holder 212.

In some embodiments, the method comprises discarding the sapphire substrate 104 removed from the LED device 101 in a trough 218 comprising a recess disposed in the stage between the third and fourth walls 235c, 235d at a depth at least equal to or greater than the depth of the first carrier holder 212. Some embodiments include removing the sapphire substrate 104 from the trough 218 using a vacuum suction device 220 in fluid communication with the stage 210. In some embodiments, the first carrier holder 212 (and any additional carrier holders) is sized to hold a carrier 110 having at least one dimension in a range from about 75 millimeters to about 300 millimeters. In some embodiments, the carrier 110 has at least one dimension in a range of about 1 millimeter to about 75 millimeters. In some embodiments, the stage 210 is mounted to a pedestal 228, and the method comprises moving the stage 210 in a vertical direction.

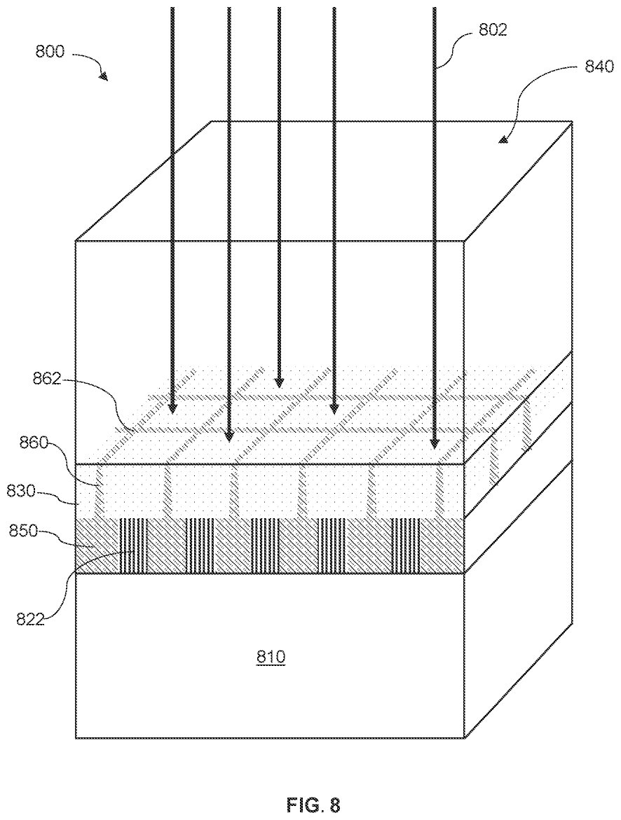

Embodiments of the disclosure can be utilized to remove a sapphire substrate 104 from an LED die after a laser lift-off procedure, wherein the LED die includes a trenched metal grid. In an exemplary embodiment, FIG. 8 illustrates in perspective view a structure 800 that allows for laser lift-off removal of a sapphire substrate 840 from contact with the LED die including a trenched metal grid 862. The structure 800 includes an LED die with semiconductor layers 830 (in which the uppermost layer is a GaN interface as described above) attached to a CMOS chip or wafer 810. Electrical and mechanical connection between the CMOS chip or wafer 810 and the semiconductor layers 830 is provided by electrically conductive pillars 822. The pillars define a cavity or gap that can be filled with an underfill material 850 to improve mechanical stability and attachment, and also improve electrical isolation.

In this embodiment, the semiconductor layers 830 include the trenched metal 860 that forms a trenched metal grid 862. In effect, trenches can help define a plurality of spaced mesas that, in turn, define pixels, with each of the plurality of spaced mesas comprising the semiconductor layers 830 and each of the spaced mesas having a height less than or equal to their width. The trenched metal 860, which is deposited in a space between each of the plurality of spaced mesas, provides optical isolation between each of the spaced mesas and allows electrical contact with sidewalls of the GaN LED. In one embodiment, electrical contact can include electrically contacting the n-type layer of each of the spaced mesas along sidewalls of the n-type layers. The space between each of the plurality of spaced mesas can result in a pixel pitch in a range of from about 1 μm to about 100 μm and space between adjacent edges of the p-contact layer of less than about 10% of the pixel pitch when the pixel pitch is in a range of from about 10 μm to about 100 μm, and when the pixel pitch is in a range of about 1 μm to about 10 μm, the space gap is less than or equal to about 5 μm and greater than about 0.5 μm.

In some embodiments, the trenched metal 860 comprises a reflective metal. In some embodiments, the trenched metal 860 width is less than or equal to about 4 μm and greater than about 0.5 μm, or less than or equal to about 3 μm and greater than about 0.5 μm. In some embodiments, the plurality of spaced mesas between the trenched metal grid 862 is arranged into pixels, and the pixel pitch ranges from about 5 μm to about 100 μm, or from about 30 μm to about 50 μm. In some embodiments, the semiconductor layers 830 have a thickness in a range of from about 2 μm to about 50 μm, for example from about 2 μm to about 30 μm, from about 2 μm to about 20 μm, or from about 2 μm to about 10 μm. In some embodiments, the thickness of the sapphire substrate 840 is in a range of from about 100 μm to about 800 μm.

Since the trenched metal 860 is attached between the sapphire substrate 840 and the semiconductor layers 830 of the LED die, sapphire lift-off requires breaking connection with the trenched metal 860. In this embodiment, laser light 802 decomposes the GaN (or other semiconductor layer 830 material) to create separation from the sapphire substrate 840. While the laser energy is not high enough to cause decomposition and direct release of the trenched metal 860, in regions where the area of semiconductor layer 830 material (e.g., GaN) is sufficiently greater than the area of the trenched metal 860, the force of nitrogen gas expansion from decomposition of semiconductor layer 830 material (e.g., GaN) causes separation of trenched metal 860 from the sapphire substrate 840. The apparatus and methods described herein can be used to remove the sapphire substrate 840 when the sapphire substrate remains adhered to the GaN interface (or other material) of the semiconductor layers 830 after laser lift-off, providing post laser lift-off processes and apparatus to complete removal of the sapphire substrate 840 from the LED die, solving a difficult and costly problem.

### EMBODIMENTS

Various embodiments are listed below. It will be understood that the embodiments listed below may be combined with all aspects and other embodiments in accordance with the scope of the disclosure, and the combination of embodiments is not limited to the combinations provided immediately below.

Embodiment 1 pertains to a light emitting diode (LED) device sapphire substrate removal apparatus comprising a stage including at least a first carrier holder sized and shaped to hold a carrier of an LED device including a sapphire substrate, the carrier holder comprising a recessed region defining an area configured to receive the carrier and a raised edge configured to hold the carrier when removing the sapphire substrate from the LED device; and a shearing device comprising a shearing blade positioned to apply a force to the sapphire substrate to remove the sapphire substrate from the LED device.

Embodiment 2 pertains to the light emitting diode (LED) device sapphire substrate removal apparatus of embodiment 1, wherein the shearing blade is movably disposed in a vertical direction with respect to the first carrier holder.

Embodiment 3 pertains to the light emitting diode (LED) device sapphire substrate removal apparatus of embodiment 1 or 2, wherein the shearing blade is movably disposed in a horizontal direction with respect to the first carrier holder.

Embodiment 4 pertains to the light emitting diode (LED) device sapphire substrate removal apparatus of embodiment 2 or 3, wherein the shearing device comprises a motor and a shaft in connection with the shearing device, wherein the motor and shaft are configured to move the shearing blade horizontally and/or vertically with respect to the first carrier holder.

Embodiment 5 pertains to the light emitting diode (LED) device sapphire substrate removal apparatus of embodiments 1-4, wherein the stage comprises a trough disposed along a side of the stage for receiving the sapphire substrate after removal from the LED device.

Embodiment 6 pertains to the light emitting diode (LED) device sapphire substrate removal apparatus of embodiment 5, wherein the trough comprises a recessed region in the stage having a depth at least equal to or greater than a depth of the first carrier holder recessed region.

Embodiment 7 pertains to the light emitting diode (LED) device sapphire substrate removal apparatus of embodiments 1-6, further comprising a vacuum suction device in fluid communication with the stage.

Embodiment 8 pertains to the light emitting diode (LED) device sapphire substrate removal apparatus of embodiment 7, further comprising a suction line connecting the stage and the vacuum suction device.

Embodiment 9 pertains to the light emitting diode (LED) device sapphire substrate removal apparatus of embodiment 5 or 6, further comprising a vacuum suction device in fluid communication with the trough.

Embodiment 10 pertains to the light emitting diode (LED) device sapphire substrate removal apparatus of embodiment 9, further comprising a suction line connecting the trough and the vacuum suction device.

Embodiment 11 pertains to the light emitting diode (LED) device sapphire substrate removal apparatus of embodiments 1-10, wherein the carrier holding device is sized to hold a carrier having one or more dimensions in a range from about 1 millimeter to about 300 millimeters.

Embodiment 12 pertains to the light emitting diode (LED) device sapphire substrate removal apparatus of embodiment 11, wherein the one or more dimensions range from about 2 millimeters to about 75 millimeters.

Embodiment 13 pertains to the light emitting diode (LED) device sapphire substrate removal apparatus of embodiments 1-12, wherein the shearing blade comprises a metal having a hardness greater than or equal to the hardness of sapphire.

Embodiment 14 pertains to the light emitting diode (LED) device sapphire substrate removal apparatus of embodiments 1-13, wherein the stage is mounted on a pedestal, and the pedestal is configured to move the stage in a vertical direction.

Embodiment 15 pertains to the light emitting diode (LED) device sapphire substrate removal apparatus of embodiments 1-13, wherein the apparatus further comprises a controller configured to control movement of the shearing blade.

Embodiment 16 pertains to the light emitting diode (LED) device sapphire substrate removal apparatus of embodiment 15, wherein the apparatus comprises a vacuum suction device in communication with the controller.

Embodiment 17 pertains to a method of removing a sapphire substrate from an LED device, the method comprising placing the LED device comprising the sapphire substrate and a carrier onto a stage; and using a shearing device to apply a force to the sapphire substrate to remove the sapphire substrate from the LED device.

Embodiment 18 pertains to the method of removing a sapphire substrate from an LED device of embodiment 17, wherein the stage includes at least a first carrier holder sized and shaped to hold the carrier of the LED device, wherein the carrier holder comprises a recessed region defining an area configured to receive the carrier and a raised edge configured to hold the carrier, and placing the LED device onto the stage comprises placing the carrier into the recessed region such that the raised edge holds the carrier with the sapphire substrate positioned above the raised edge.

Embodiment 19 pertains to the method of removing a sapphire substrate from an LED device of embodiment 17 or 18, wherein the shearing device comprises a shearing blade, and wherein applying the force to the sapphire substrate to remove the sapphire substrate from the LED device comprises moving the shearing blade relative to the first carrier holder to apply the force to the sapphire substrate.

Embodiment 20 pertains to the method of removing a sapphire substrate from an LED device of embodiment 19, wherein the shearing blade is movable relative to the first carrier holder in at least one of a vertical direction and a horizontal direction, and wherein applying the force to the sapphire substrate comprises moving the shearing blade in at least one of a vertical direction and a horizontal direction.

Embodiment 21 pertains to the method of removing a sapphire substrate from an LED device of embodiment 19 or 20, further comprising, prior to applying the force to the sapphire substrate to remove the sapphire substrate from the LED device, moving the shearing blade in at least one of a vertical direction and a horizontal direction to position the shearing blade adjacent the sapphire substrate.

Embodiment 22 pertains to the method of removing a sapphire substrate from an LED device of embodiments 19-21, wherein applying the force to the sapphire substrate to remove the sapphire substrate from the LED device comprises moving the shearing blade horizontally to engage and separate the sapphire substrate from the LED device.

Embodiment 23 pertains to the method of removing a sapphire substrate from an LED device of embodiments 19-22, further comprising using a motor and a shaft configured to move the shearing blade horizontally and vertically with respect to the first carrier holder.

Embodiment 24 pertains to the method of removing a sapphire substrate from an LED device of embodiments 17-23, further comprising discarding the sapphire substrate removed from the LED device in a trough positioned in the stage.

Embodiment 25 pertains to the method of removing a sapphire substrate from an LED device of embodiment 24, further comprising removing the sapphire substrate from the trough using a vacuum suction device in fluid communication with the stage.

Embodiment 26 pertains to the method of removing a sapphire substrate from an LED device of embodiment 18, wherein the carrier holding device is sized to hold a carrier having at least one dimension in a range from about 75 millimeters to about 300 millimeters.

Embodiment 27 pertains to the method of removing a sapphire substrate from an LED device of embodiment 26, wherein the carrier holding device is sized to hold a carrier having at least one dimension in a range of about 1 millimeter to about 75 millimeters. In

Embodiment 28 pertains to the method of removing a sapphire substrate from an LED device of embodiments 17-27, wherein the stage mounted to a pedestal configured to move the stage in a vertical direction.

Embodiment 29 pertains to the method of removing a sapphire substrate from an LED device of embodiments 17-28, further comprising removing the LED device from the stage after the sapphire substrate has been removed from the LED device.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents. Therefore, it is understood the method and apparatus of the present disclosure is not to be limited to the specific embodiments disclosed, and that modifications and embodiments are intended to be included within the scope of the appended claims. It is also understood that other embodiments of the method and apparatus of the present disclosure may be practiced in the absence of an element/step not specifically disclosed herein.

1. A light emitting diode (LED) device sapphire substrate removal apparatus comprising:
a stage including at least a first carrier holder sized and shaped to hold a carrier of an LED device including a sapphire substrate, the carrier holder comprising a recessed region defining an area configured to receive the carrier and a raised edge configured to hold the carrier when removing the sapphire substrate from the LED device; and
a shearing device comprising a shearing blade positioned to apply a force to the sapphire substrate to remove the sapphire substrate from the LED device.

2. The LED device sapphire substrate removal apparatus of claim 1, wherein the shearing blade is movably disposed in a vertical direction with respect to the first carrier holder.

3. The LED device sapphire substrate removal apparatus of claim 2, wherein the shearing blade is movably disposed in a horizontal direction with respect to the first carrier holder.

4. The LED device sapphire substrate removal apparatus of claim 3, wherein the shearing device comprises a motor and a shaft in connection with the shearing device, wherein the motor and shaft are configured to move the shearing blade horizontally and/or vertically with respect to the first carrier holder.

5. The LED device sapphire substrate removal apparatus of claim 1, wherein the stage is enclosed by one or more walls.

6. The LED device sapphire substrate removal apparatus of claim 1, wherein the stage further comprises a trough disposed along a side of the stage for receiving the sapphire substrate after removal from the LED device.

7. The LED device sapphire substrate removal apparatus of claim 1, further comprising a vacuum suction device in fluid communication with the stage.

8. The LED device sapphire substrate removal apparatus of claim 1, wherein the shearing blade comprises a metal having a hardness greater than or equal to the hardness of sapphire.

9. The LED device sapphire substrate removal apparatus of claim 1, wherein the stage is mounted to a pedestal, and wherein the pedestal is configured to move the stage in a vertical direction.

10. The LED device sapphire substrate removal apparatus of claim 4, further comprising a controller configured to control movement of the shearing blade.

11. A method of removing a sapphire substrate from an LED device, the method comprising:
placing the LED device comprising the sapphire substrate and a carrier onto a stage; and
using a shearing device to apply a force to the sapphire substrate to remove the sapphire substrate from the LED device.

12. The method of claim 11, wherein the stage includes at least a first carrier holder sized and shaped to hold the carrier of the LED device, wherein the carrier holder comprises a recessed region defining an area configured to receive the carrier and a raised edge configured to hold the carrier, and placing the LED device onto the stage comprises placing the carrier into the recessed region such that the raised edge holds the carrier with the sapphire substrate positioned above the raised edge.

13. The method of claim 12, wherein the shearing device comprises a shearing blade, and wherein applying the force to the sapphire substrate comprises moving the shearing blade relative to the first carrier holder to apply the force to the sapphire substrate.

14. The method of claim 13, wherein the shearing blade is movable relative to the first carrier holder in at least one of a vertical direction and a horizontal direction, and wherein applying the force to the sapphire substrate comprises moving the shearing blade in at least one of a vertical direction and a horizontal direction.

15. The method of claim 14, further comprising, prior to applying the force to the sapphire substrate to remove the sapphire substrate from the LED device, moving the shearing blade in at least one of a vertical direction and a horizontal direction to position the shearing blade adjacent the sapphire substrate.

16. The method of claim 15, wherein applying the force to the sapphire substrate to remove the sapphire substrate from the LED device comprises moving the shearing blade horizontally to engage and separate the sapphire substrate from the LED device.

17. The method of claim 16, further comprising discarding the sapphire substrate removed from the LED device in a trough disposed in the stage.

18. The method of claim 17, further comprising removing the sapphire substrate from the trough using a vacuum suction device in fluid communication with the stage.

19. The method of claim 14, wherein the shearing device comprises a motor and a shaft configured to move the shearing blade horizontally and vertically relative to the first carrier holder.

20. The wherein of claim 14, wherein the stage is mounted to a pedestal configured to move the stage in a vertical direction.
